(19) United States
(12) Patent Application Publication
(10) Pub. No.: US 2025/0105152 A1
(43) Pub. Date: Mar. 27, 2025

(54) SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventor: Hansae Lim, Suwon-si (KR)

(21) Appl. No.: 18/823,789

(22) Filed: Sep. 4, 2024

(30) Foreign Application Priority Data
Sep. 25, 2023 (KR) 10-2023-0128142
Oct. 24, 2023 (KR) 10-2023-0142985

(51) Int. Cl. H01L 23/528; H01L 21/56; H01L 23/00; H01L 23/31

(52) U.S. Cl. CPC H01L 23/5283; H01L 24/13; H01L 24/16; H01L 21/56; H01L 23/3128; H01L 24/81; H01L 2224/13005; H01L 2224/13552; H01L 2224/16227; H01L 2224/81203; H01L 2924/1431; H01L 2924/1436; H01L 2924/1438; H01L 2924/301

(57) ABSTRACT

A semiconductor package includes a package substrate including wirings having a plurality of pad patterns that respectively extend such that at least a portion of each of the pad patterns is exposed in at least one pad open region, a semiconductor chip mounted on the chip mounting region of the package substrate by a plurality of conductive bumps, and a sealing member on the semiconductor chip on the package substrate. Each of the plurality of pad patterns includes a main line extending in a first direction away from one side of the pad open region, and a branch line extending in a second direction different from the first direction from an end portion of the main line or from a position laterally spaced apart from the end portion of the main line.

### CLAIM OF PRIORITY

This application claims priority under 35 U.S.C. § 119 to Korean Patent Application Nos. 10-2023-0128142, filed on Sep. 25, 2023 and 10-2023-0142985, filed on Oct. 24, 2023 in the Korean Intellectual Property Office (KIPO), the contents of which are herein incorporated by reference in their entirety.

### FIELD

Example embodiments relate to a semiconductor package and a method of manufacturing the semiconductor package. More particularly, example embodiments relate to a semiconductor package including a semiconductor chip stacked in a flip chip bonding manner and a method of manufacturing the same.

### BACKGROUND

In a semiconductor package using a flip chip bonding manner, a semiconductor chip may be mounted on a package substrate using conductive bumps. The bump may be soldered through a thermal compression process and bonded to a wiring pad of the package substrate. However, during the thermal compression process, the softened bump may overflow along the wiring and come into contact with adjacent pads, causing a short circuit.

### SUMMARY

Example embodiments provide a semiconductor package having a structure that is able to reduce or prevent short circuit defects caused by soldering.

Example embodiments provide a method of manufacturing the semiconductor package.

According to example embodiments, a semiconductor package includes a package substrate comprising a chip mounting region and at least one pad open region in the chip mounting region, the package substrate including wirings having a plurality of pad patterns that respectively extend such that at least a portion of each of the pad patterns is exposed in the at least one pad open region; a semiconductor chip mounted on the chip mounting region of the package substrate by a plurality of conductive bumps; and a sealing member on the semiconductor chip on the package substrate. The plurality of pad patterns are laterally spaced apart from each other, and the each of the pad patterns includes a main line extending in a first direction away from one side of the pad open region, and a branch line extending in a second direction different from the first direction. The branch line extends from an end portion of the main line with each of the conductive bumps on an upper surface of the branch line, or the branch line extends from a position laterally spaced apart from the end portion of the main line with each of the conductive bumps on an upper surface of a portion of the main line that is between the end portion and the position from which the branch line extends.

According to example embodiments, a semiconductor package includes a package substrate comprising at least one pad open region, the package substrate including wirings having a plurality of pad patterns that respectively extend such that at least a portion of each of the pad patterns is exposed in the at least one pad open region; a semiconductor chip comprising a plurality of chip pads on a first surface thereof and oriented such that the first surface faces an upper surface of the package substrate; a plurality of conductive bumps on the plurality of chip pads, respectively, wherein the conductive bumps bond the plurality of chip pads to respective portions of the plurality of pad patterns; and a sealing member on the semiconductor chip on the package substrate, the sealing member at least partially surrounding the plurality of conductive bumps between the package substrate and the semiconductor chip. The each of the pad patterns includes a main line extending in a first direction away from one side of the pad open region, and a branch line extending in a second direction different from the first direction from a position laterally spaced apart from an end portion of the main line. Each of the conductive bumps is on an upper surface of a portion of the main line that is between the end portion and the position from which the branch line extends.

According to example embodiments, a package substrate comprising at least one pad open region, the package substrate including wirings having a plurality of pad patterns that respectively extend such that at least a portion of each of the pad patterns is exposed in the at least one pad open region; a semiconductor chip comprising a plurality of chip pads on a first surface thereof and oriented such that the first surface faces an upper surface of the package substrate; a plurality of conductive bumps on the plurality of chip pads, respectively, wherein the conductive bumps bond the plurality of chip pads to respective portions of the plurality of pad patterns; and a sealing member on the semiconductor chip on the package substrate, the scaling member at least partially surrounding the plurality of conductive bumps between the package substrate and the semiconductor chip. Each of the pad patterns includes a main line extending in a first direction away from one side of the pad open region, and a branch line extending in a second direction different from the first direction from an end portion of the main line. Each of the conductive bumps is on an upper surface of the branch line.

According to example embodiments, a semiconductor package may include a package substrate having a plurality of pad patterns that respectively extend such that at least a portion of each pad pattern is exposed in a pad open region, and a semiconductor chip mounted on an upper surface of the package substrate by a plurality of conductive bumps. Each of the plurality of pad patterns may include a main line that extends in a third direction away from one side of the pad open region and a branch line that extends in a second direction different from the first direction from an end portion of the main line or from a position laterally spaced apart from the end portion of the main line.

Each of the conductive bumps may be on an upper surface of the branch line or on an upper surface of a portion of the main line between the end portion of the main line and a branched portion of the main line. A solder layer of the conductive bump may at least partially fill a space between a side wall of the branch line and a side wall of the main line.

Accordingly, short circuit defects between adjacent main lines and branch lines due to overflow of the solder layer may be reduced or prevented.

### BRIEF DESCRIPTION OF THE DRAWINGS

Example embodiments will be more clearly understood from the following detailed description taken in conjunction with the accompanying drawings. FIGS. 1 to 35 represent non-limiting, example embodiments as described herein.

FIG. 1 is a plan view illustrating a semiconductor package in accordance with example embodiments.

FIG. 2 is a cross-sectional view taken along the line A-A′ in FIG. 1.

FIG. 3 is a plan view illustrating conductive bumps on a package substrate in FIG. 2.

FIG. 4 is an enlarged plan view illustrating portion ‘B’ in FIG. 3.

FIG. 5 is a cross-sectional view taken along the line C-C′ in FIG. 4.

FIG. 6 is a cross-sectional view taken along the line D-D′ in FIG. 4.

FIG. 7 is a cross-sectional view taken along line E-E′ in FIG. 4.

FIG. 8 is a perspective view illustrating a conductive bump bonded on a pad pattern in FIG. 4.

FIGS. 9, 10, 11, 12, 13, 14, 15, 16, 17, 18, 19, 20, and 21 are views illustrating a method of manufacturing a semiconductor package in accordance with example embodiments.

FIG. 22 is a cross-sectional view illustrating a semiconductor package in accordance with example embodiments.

FIG. 23 is a plan view illustrating conductive bumps on a package substrate in FIG. 22.

FIG. 24 is an enlarged plan view illustrating portion ‘L’ in FIG. 23.

FIG. 25 is a cross-sectional view taken along the line M-M′ in FIG. 24.

FIG. 26 is a cross-sectional view taken along the line N-N′ in FIG. 24.

FIG. 27 is a cross-sectional view taken along the line O-O′ in FIG. 24.

FIG. 28 is a cross-sectional view taken along the line P-P′ in FIG. 24.

FIG. 29 is a perspective view illustrating a conductive bump bonded on a pad pattern of FIG. 23.

FIGS. 30, 31, 32, 33, 34, and 35 are cross-sectional views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

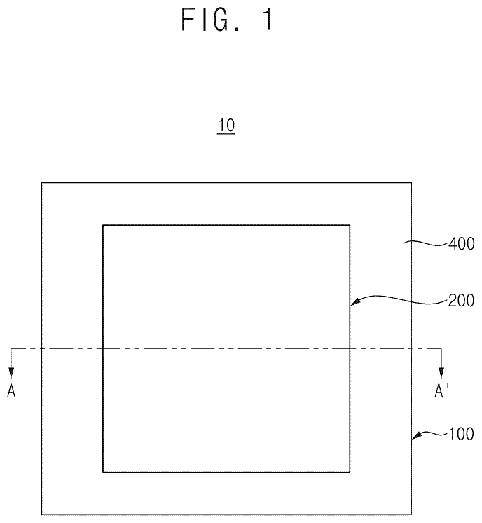

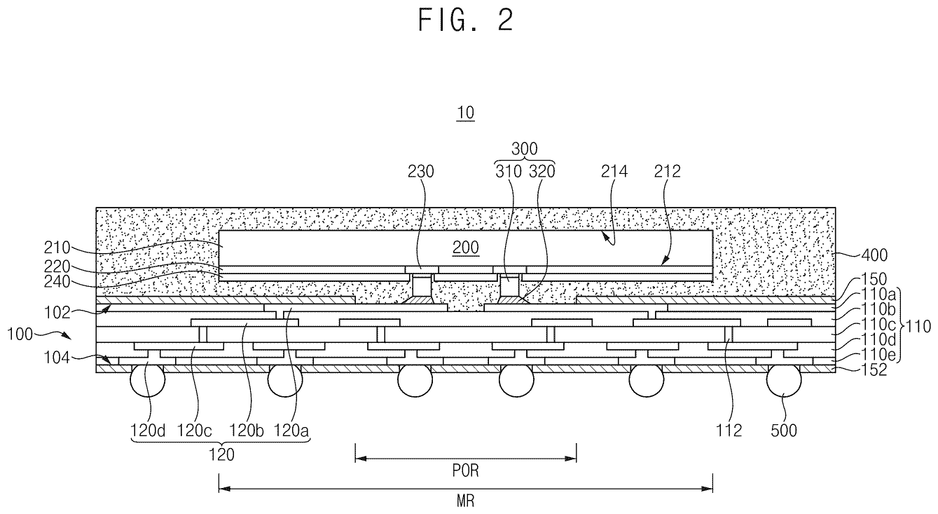

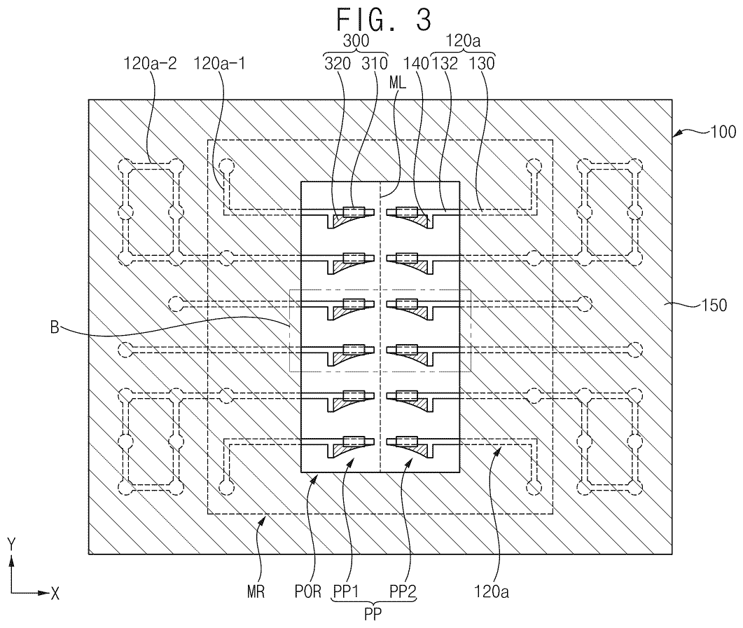

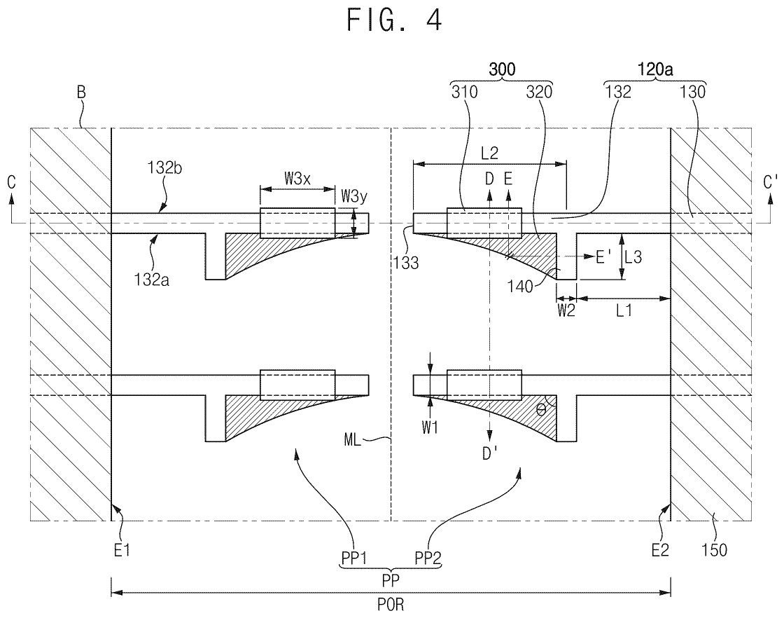

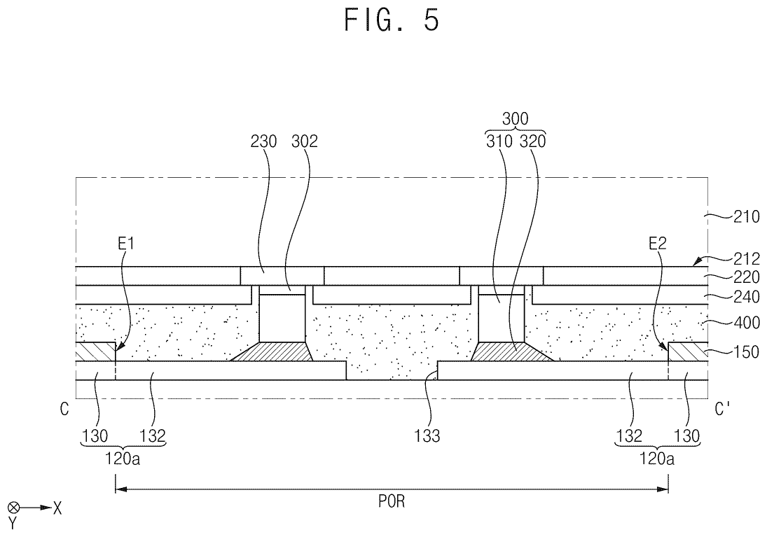

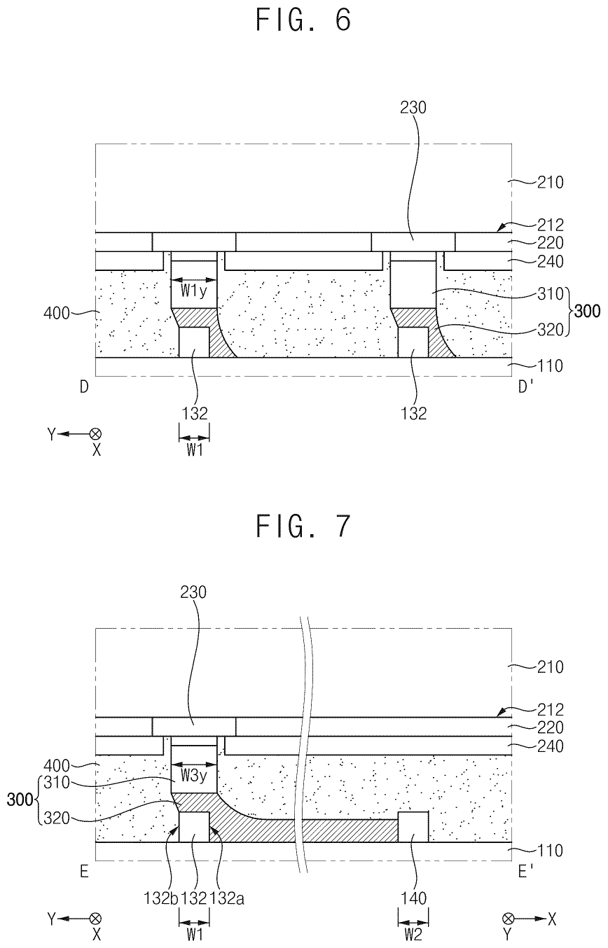

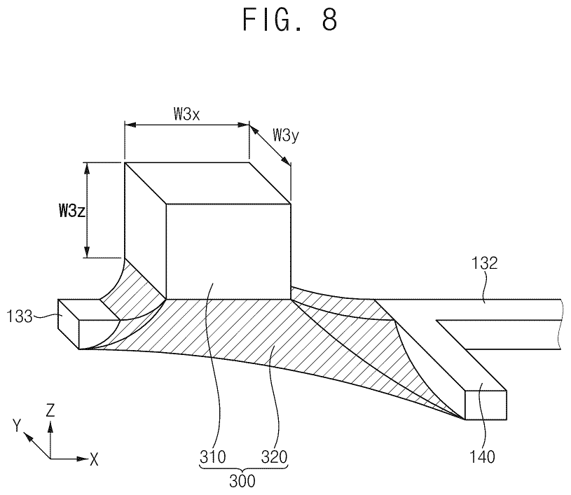

FIG. 1 is a plan view illustrating a semiconductor package in accordance with example embodiments. FIG. 2 is a cross-sectional view taken along the line A-A′ in FIG. 1. FIG. 3 is a plan view illustrating conductive bumps on a package substrate in FIG. 2. FIG. 4 is an enlarged plan view illustrating portion ‘B’ in FIG. 3. FIG. 5 is a cross-sectional view taken along the line C-C′ in FIG. 4. FIG. 6 is a cross-sectional view taken along the line D-D′ in FIG. 4. FIG. 7 is a cross-sectional view taken along line E-E′ in FIG. 4. FIG. 8 is a perspective view illustrating a conductive bump bonded on a pad pattern in FIG. 4.

Referring to FIGS. 1 to 8, a semiconductor package 10 may include a package substrate 100, a semiconductor chip 200, a plurality of conductive bumps 300, and a molding member 400. Additionally, the semiconductor package 10 may further include external connection members 500.

In example embodiments, the package substrate 100 may be a multilayer circuit board having an upper surface 102 and a lower surface 104 opposite to the upper surface 102. For example, the package substrate 100 may be a printed circuit board (PCB) including wirings provided in a plurality of layers and vias connected to the wirings. Spatially relative terms such as ‘top,’ ‘above,’ ‘upper,’ ‘upper portion,’ ‘upper surface,’ ‘bottom,’ ‘below,’ ‘lower,’ ‘lower portion,’ ‘lower surface,’ ‘side surface,’ and the like may be denoted by reference numerals and refer to the orientations illustrated by way of example in the drawings. It will be understood that such spatially relative terms are intended to encompass different orientations of the device in addition to the orientation depicted in the figures.

In particular, the package substrate 100 may include a plurality of stacked insulating layers 110 and wirings 120a, 120b, 120c, and 120d respectively provided in the insulating layers.

As illustrated in FIG. 2, the package substrate 100 may include first, second, third, fourth and fifth insulating layers 110a, 110b, 110c, 110d, and 110e sequentially stacked. The first insulating layer 110a may be an upper cover insulating layer, the second insulating layer 110b may be an upper insulating layer, the third insulating layer 110c may be a core layer, the fourth insulating layer 110d may be a lower insulating layer, and the fifth insulating layer 110e may be a lower cover insulating layer. The third insulating layer 110c as the core layer may include a non-conductive material layer. The third insulating layer 110c may include a reinforcing polymer or the like.

A second wiring 120b may be provided on an upper surface of the third insulating layer 110c. The second insulating layer 110b may cover the second wiring 120b on the upper surface of the third insulating layer 110c. A first wiring 120a may be provided on an upper surface of the second insulating layer 110b and may be electrically connected to the second wiring 120b through an opening formed in the second insulating layer 110b.

A third wiring 120c may be provided on a lower surface of the third insulating layer 110c. The fourth insulating layer 110d may cover the third wiring 120c on the lower surface of the third insulating layer 110c. A fourth wiring 120d may be provided on a lower surface of the fourth insulating layer 110d and may be electrically connected to the third wiring 120c through an opening formed in the fourth insulating layer 110d.

The first to fourth wirings 120a, 120b, 120c, and 120d may be referred to as first to fourth circuit layers stacked in a thickness direction from the upper surface 102 to the lower surface 104 of the package substrate 100. For example, the wiring may include metal materials such as copper, aluminum, etc. It will be understood that the arrangements and numbers of the insulating layers and the wirings are exemplary and not limited thereto.

A conductive through via 112 may penetrate the third insulating layer 110c as the core layer and electrically connect the second wiring 120b and the third wiring 120c. The first wiring 120a may be exposed from the upper surface 102 of the package substrate 100. The fourth wiring 120d may be exposed from the lower surface 104 of the package substrate 100. The term “exposed” may be used herein to describe relationships between elements and/or certain intermediate processes in fabricating a completed semiconductor device, but may not require external exposure of the particular region, layer, structure or other element in the context of the completed device.

An upper insulating layer 150 may be provided on the upper surface 102 of the package substrate 100 and may expose at least a portion of the first wiring 120a. A lower insulating layer 152 may be provided on the lower surface 104 of the package substrate 100 and may expose at least a portion of the fourth wiring 120d. The upper insulating layer 150 and the lower insulating layer 152 may separate the circuit patterns of the package substrate 100 from the external environment to reduce or prevent contamination and electrically insulate the wirings of the circuit patterns from each other. For example, the upper insulating layer and the lower insulating layer may include a photosensitive resin such as photo epoxy or a photosensitive polymer such as photo solder resist (PSR).

In addition, the first wires 120a may include a data signal wiring 120a-1 for transmitting data signals to the semiconductor chip 200 mounted on the package substrate 100 and a power/ground wiring 120a-2 for transmitting a power signal or a ground signal to the semiconductor chip 200. The data signal wiring 120a-1, which functions as a data transmission pattern, may be provided as a single wire line, and the power/ground wiring 120a-2, which functions as a power pattern or ground wire, may be provided as a plurality of wire lines and may be electrically connected to each other.

As illustrated in FIG. 3, the package substrate 100 may have a chip mounting region MR and at least one pad open region POR within the chip mounting region MR. The semiconductor chip 200 may be mounted in the chip mounting region MR on the upper surface 102 of the package substrate 100. The upper insulating layer 150 may expose portions of the wirings 120a in the pad open region POR.

The pad open region POR may correspond to a center pad area where chip pads 230 of the semiconductor chip 200 are arranged. Portions of the first wirings 120a in the pad open region POR exposed by the upper insulating layer 150 may be referred to as pad patterns PP o which conductive bumps 300 are disposed respectively such that the semiconductor chip 200 is mounted by the flip chip bonding method.

The plurality of pad patterns PP may be arranged to be spaced apart from each other along one side of the pad open region POR. For example, the plurality of pad patterns PP may include a first group of pad patterns PP1 and a second group of pad patterns PP2 that are spaced apart from each other in a first direction (X direction), also referred to herein as being laterally spaced apart in the first direction. The first group of pad patterns PP1 may be arranged to be spaced apart from each other in a second direction (Y direction) perpendicular to the first direction (X direction) along a first side E1 of the pad open region POR (also referred to herein as being laterally spaced apart in the second direction), and the second group of pad patterns PP2 may be spaced apart from each other in the second direction (Y direction) along a second side E2 that faces the first side E1 of the pad open region POR. A “lateral” direction, as used herein, may refer to any direction in the X-Y plane (as shown in plan views in the drawings), and may be perpendicular to a vertical (Z) direction.

The first group of pad patterns PP1 and the second group of pad patterns PP2 may be symmetrical to each other with respect to a center line ML of the pad open region POR that extends parallel to the second direction (Y direction). The first group of pad patterns PP1 arranged in the second direction (Y direction) may have the same shapes. The second group of pad patterns PP2 arranged in the second direction (Y direction) may have the same shapes.

In example embodiments, the semiconductor chip 200 may be mounted on the package substrate 100 using a flip chip bonding method. The semiconductor chip 200 may be mounted on the package substrate 100 via the conductive bumps 300. In this case, the semiconductor chip 200 may be mounted on the package substrate 100 such that an active surface on which the chip pads 230 are formed, that is, a first surface 212, faces the package substrate 100. A planar area of the semiconductor chip 200 may be smaller than a planar area of the package substrate 100. When viewed in plan view, the semiconductor chip 200 may be disposed within the chip mounting region MR of the package substrate 100.

The semiconductor chip 200 may include a memory chip such as a DRAM device or a flash memory device, or a non-memory chip such as a logic chip. The semiconductor chip 200 may include a plurality of chip pads 230 provided on the first surface 212. The chip pads 230 may have a center pad type pad structure where the chip pads 230 are arranged in a row along the center line. For example, two chip pads 230 adjacent to each other may be arranged in a row along the center line.

The conductive bumps 300 may be formed on the chip pads 230, respectively. Each of the plurality of conductive bumps 300 may include a connection pillar 310 that extends in a vertical direction from the chip pad 230 of the semiconductor chip 200 and a solder layer 320 bonded to an end portion of the connection pillar 310. For example, the connection pillar 310 may include a first metal, and the solder layer 320 may include a second metal different from the first metal. The first metal may include nickel (Ni), copper (Cu), palladium (Pd), platinum (Pt), etc. The second metal may include tin (Sn), tin/silver (Sn/Ag), tin/copper (Sn/Cu), tin/indium (Sn/In), etc.

When the semiconductor chip 200 is mounted on the package substrate 100, the conductive bumps 300 on the chip pads 230 may be respectively disposed on the pad patterns PP of the first wirings 120a, and the solder layer 320 may be softened and bonded to the pad patterns PP by a thermal compression process.

As illustrated in FIG. 4, each of the pad patterns PP may include a main line 132 and a branch line 140. The main line 132 may extend in a third direction from one side (E1, E2) of the pad open region (POR) inwardly, that is, away from one side (E1, E2) and toward a central region and/or a laterally adjacent pad pattern PP. The first wiring 120a may include a wiring line 130 covered by the upper insulating layer 150 and the main line 132 exposed by the upper insulating layer 150.

The branch line 140 may extend in a fourth direction different from the third direction at a position spaced apart from an end portion 133 of the main line 132 by a predetermined distance L2. The branch line 140 may extend from one side wall 132a of the main line 132 in the fourth direction. An angle θ between the main line 132 and the branch line 140 may be greater than, less than, or equal to 90 degrees. For example, the third direction may be parallel to X direction, and the fourth direction may be parallel to Y direction.

The branch lines 140 of the first group of pad patterns PP1 arranged along the first side E1 of the pad open region POR may extend in the same direction (fourth direction). The branch lines 140 of the second group of pad patterns PP2 arranged along the second side E2 of the pad open region POR may extend in the same direction (fourth direction).

When the semiconductor chip 200 is placed on the package substrate 100, a portion of the main line 132 between the end portion 133 of the main line 132 and a branched portion of the main line 132 to which the branch line 140 is connected may serve as a landing pad on which the conductive bump 300 is disposed. The conductive bump 300 may be disposed on the portion of the main line 132, and during the thermal compression process, the solder layer 320 may be heated and softened, and flow along the main line 132 and the branch line 140 and then be joined.

As illustrated in FIG. 5, in the first group of pad patterns PP1 and the second group of pad patterns PP2 spaced apart from each other in the first direction (X direction), the solder layers 320 may flow in directions away from each other (opposite directions) and then be bonded to portions of the branch lines 140, respectively. Accordingly, it may be possible to reduce or prevent short circuit defects from occurring due to overflow of the solder layer 320 between adjacent main lines 132 of the first group of pad patterns PP1 and the second group of pad patterns PP2.

As illustrated in FIG. 6, in the second group of pad patterns PP2 spaced apart from each other in the second direction (Y direction) along one side E2 of the pad open region POR, each solder layer 320 may flow to the branch line 140 extending in the same direction (fourth direction) and may be bonded to the portion of branch lines 140. Accordingly, it may be possible to reduce or prevent short circuit defects from occurring between adjacent main lines 132 due to overflow of the solder layer 320.

As illustrated in FIGS. 7 and 8, a portion of the solder layer 320 may flow along the main line 132 and the branch line 140 and then flows to fill a space between the side wall 132a of the main line 132 and one side wall of the branch line 140. The term “filling” or “covering” or “surrounding” as may be used herein may not require completely filling or covering or surrounding the described elements or layers, but may, for example, refer to partially filling or covering or surrounding the described elements or layers, for example, with voids or other spaces throughout.

For example, the branch line 140 may be laterally spaced apart from one side E2 of the pad open region POR by a first distance L1. The first distance L1 may be within a range of 20 μm to 40 μm. The branch line 140 may extend a third length L3 in the fourth direction. The third length L3 of the branch line 140 may be within a range of 10 μm to 30 μm. A lateral spacing distance L2 from the end portion 133 of the main line 132 to the position where the branch line 140 branches off may be within a range of 50 μm to 100 μm. A first width W1 of the main line 132 and the second width W2 of the branch line 140 may be within a range of 10 μm to 30 μm.

A long side (W3x) of the connection pillar 310 may be within a range of 40 μm to 80 μm, and a short side (W3y) of the connection pillar 310 may be within a range of 30 μm to 60 μm. An extending direction of the long side W3x of the connection pillar 310 (also referred to herein as a longitudinal extension direction of the pillar 310) may be parallel to the third direction, and an extending direction of the short side W3y of the connection pillar 310 may be parallel to the fourth direction. A height W3z of the connection pillar 310 may be within a range of 20 μm to 50 μm. A height (thickness) of the solder layer 320 may be within a range of 5 μm to 20 μm.

In example embodiments, the molding or other sealing member 400 may be provided on the package substrate 100 to protect the semiconductor chip 200 from the outside (i.e., from the external environment). The sealing member 400 may serve as an underfill member that fills a space between the package substrate 100 and the semiconductor chip 200. The sealing member 400 may cover the conductive bumps 300 between the package substrate 100 and the semiconductor chip 200. The sealing member may include an epoxy mold compound (EMC).

The external connection members 500 may be provided on external connection pads on the lower surface 104 of the package substrate 100, that is, on portions of the fourth wiring 120d exposed by the lower insulating layer 152. For example, the external connection member 500 may be a solder ball. The semiconductor package 10 may be mounted on a module substrate using the solder balls to form a memory module.

As mentioned above, the semiconductor package 10 may include the package substrate 100 having the plurality of pad patterns PP that respectively extend such that at least a portion of each pad pattern is exposed within the pad open region POR, and the semiconductor chip 200 mounted on the upper surface 102 of the package substrate 100 via the plurality of conductive bumps 300.

Each of the plurality of pad patterns PP may include the main line 132 that extends in the third direction from one side E1 and E2 of the pad open region POR inwardly and the branch line 140 that extends in the fourth direction different from the third direction at a position laterally spaced apart from the end portion 133 of the main line 132 by a predetermined distance L2. Each of the conductive bumps 300 may be disposed on the portion of the main line 132 between the end portion 133 of the main line 132 and the branch line 140.

The branch lines 140 may be formed to extend in the same direction (fourth direction), which is different from the direction of extension (third direction) of adjacent main lines 132, so that each solder layer 320 of the conductive bumps 300 may flow to the branch line 140 extending in the same direction (fourth direction) and then be joined to the portion of the branch line 140. Accordingly, it may be possible to reduce or prevent short circuit defects from occurring between adjacent main lines 132 due to overflow of the solder layer 320.

Hereinafter, a method of manufacturing the semiconductor package in FIG. 1 will be explained.

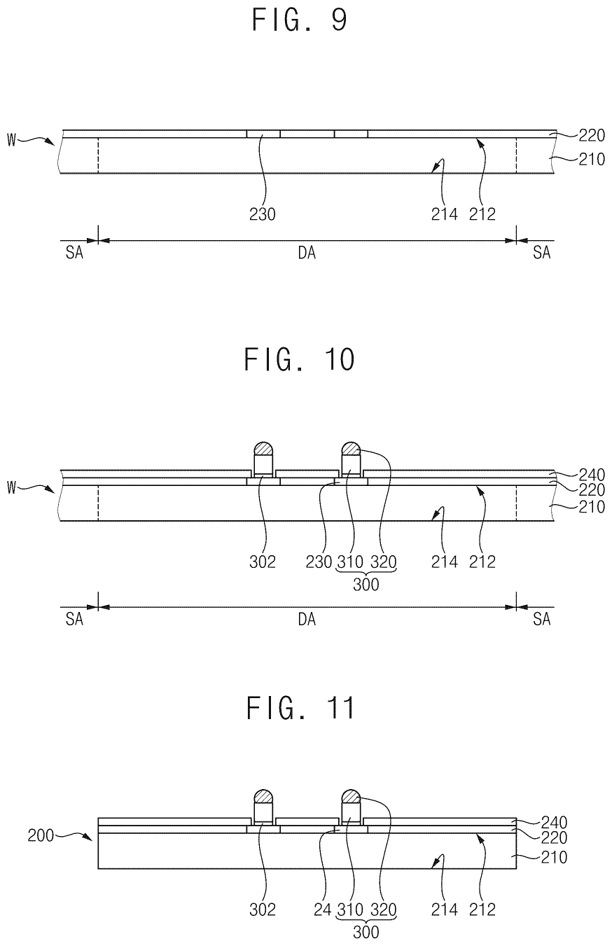

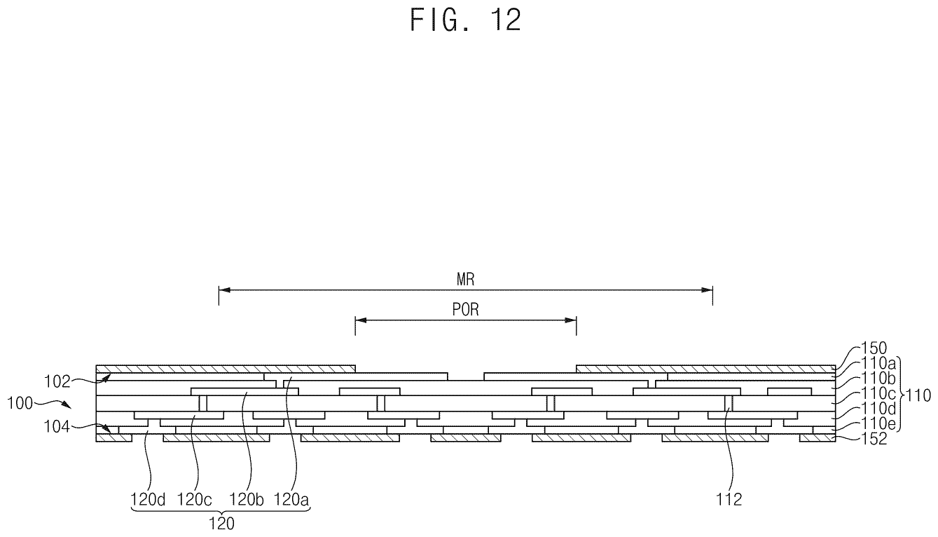

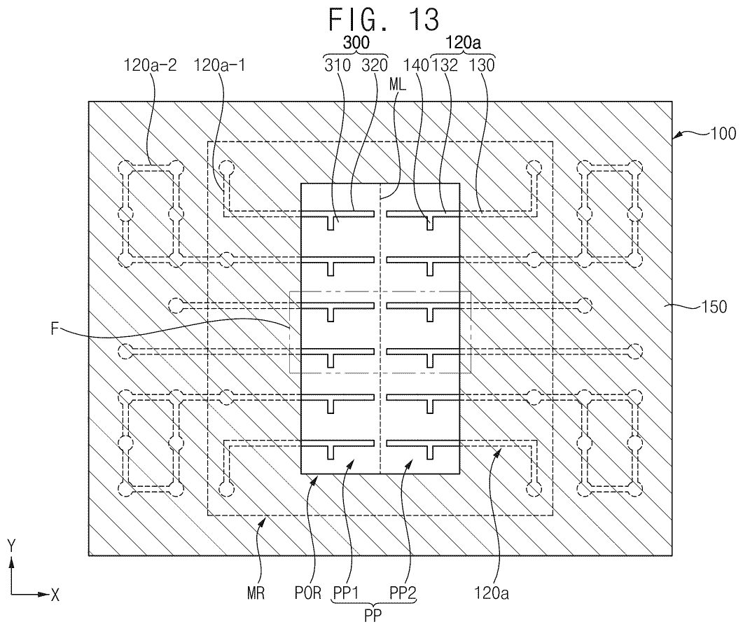

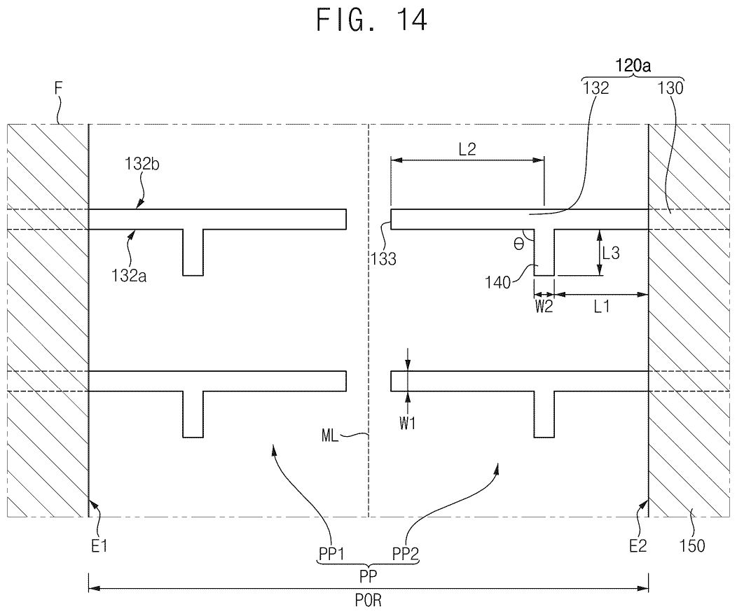

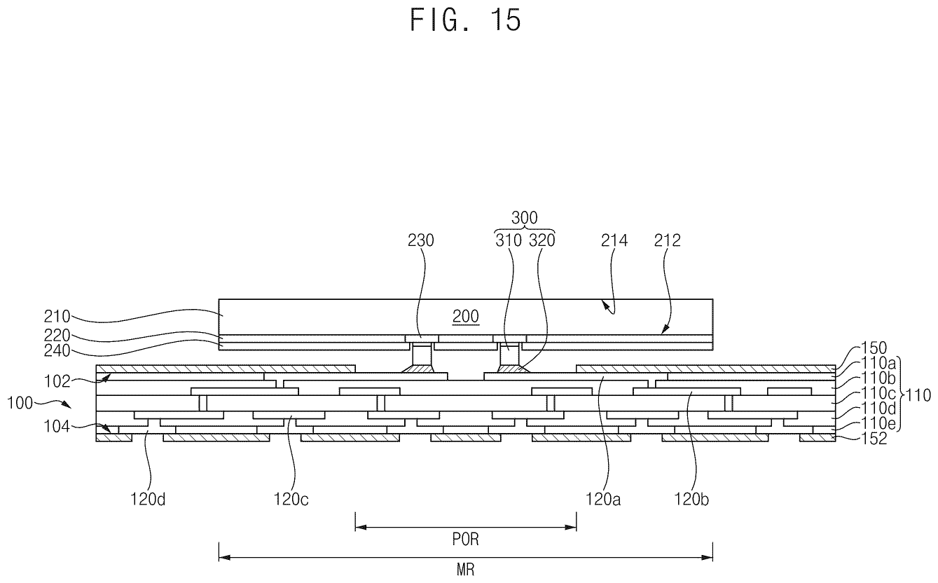

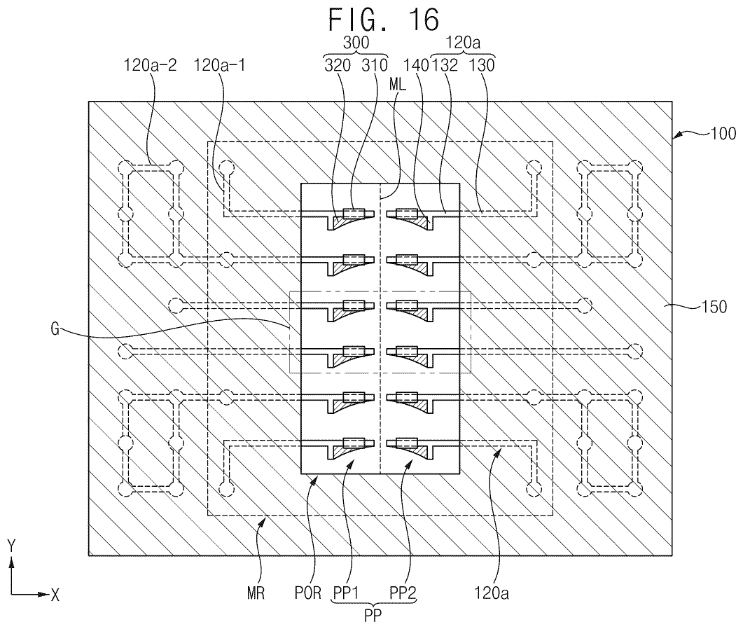

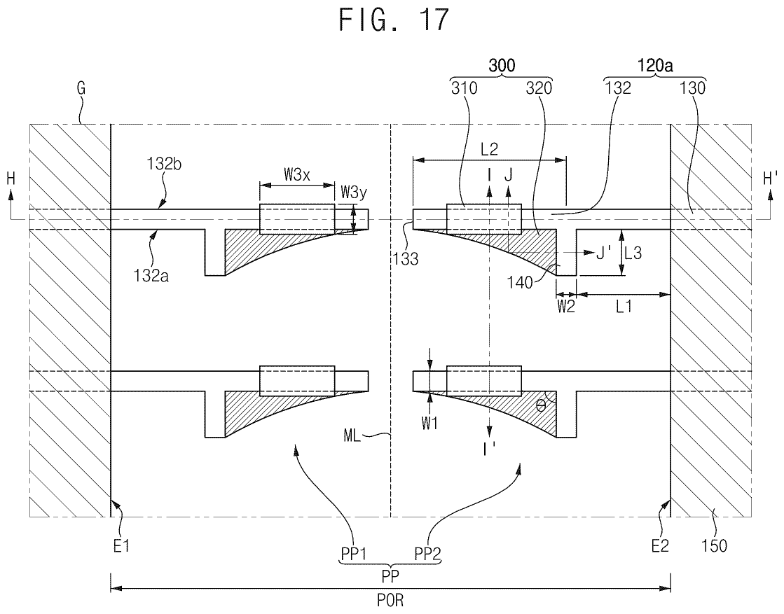

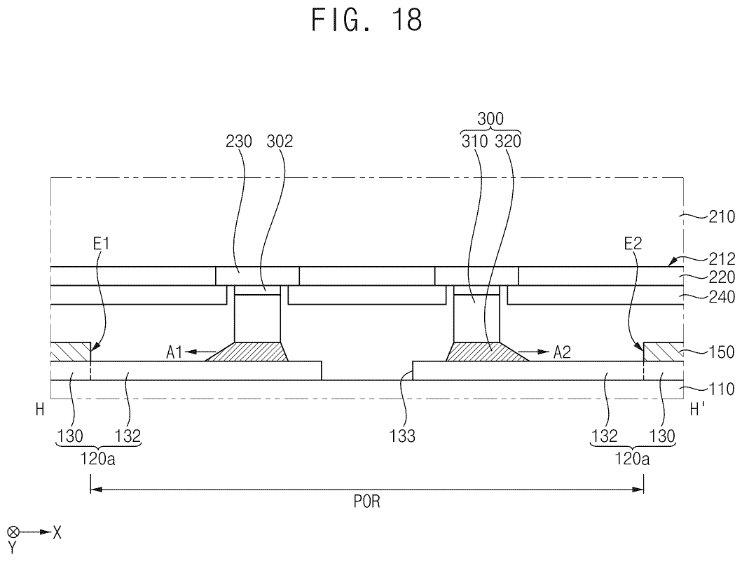

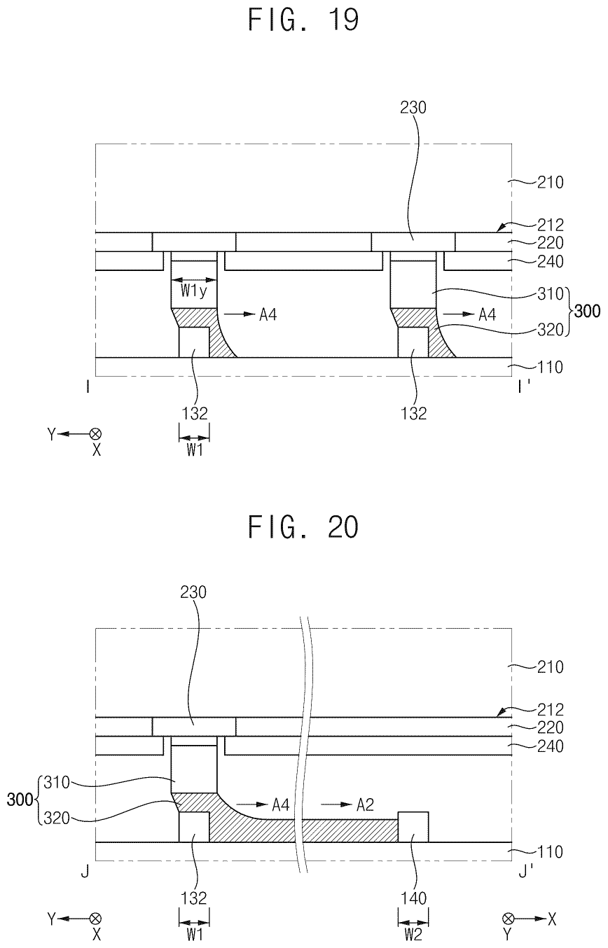

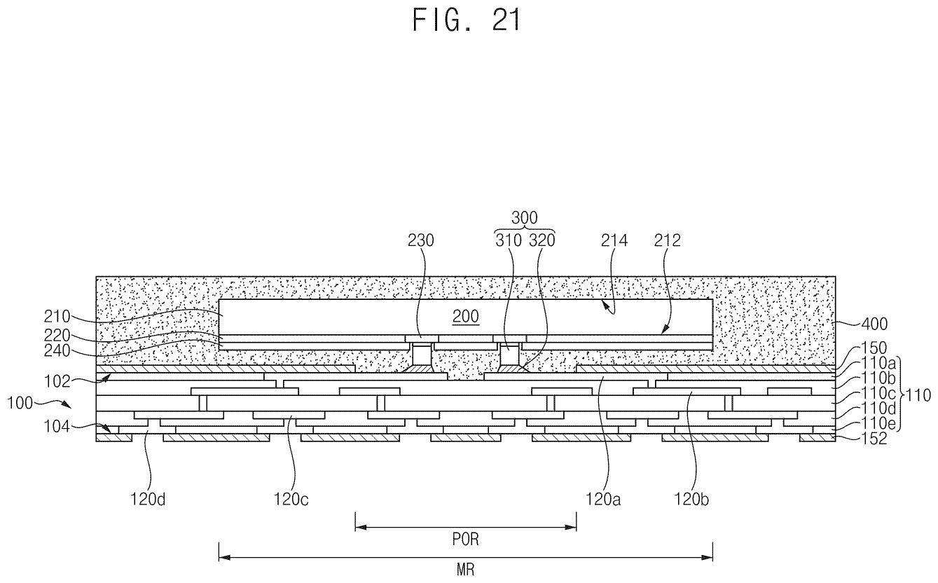

FIGS. 9 to 21 are views illustrating a method of manufacturing a semiconductor package in accordance with example embodiments. FIGS. 9, 10, 11, 12, 15 and 21 are cross-sectional views illustrating a method of manufacturing a semiconductor package in accordance with example embodiments. FIG. 13 is a plan view of FIG. 12. FIG. 14 is an enlarged cross-sectional view illustrating portion ‘F’ in FIG. 13. FIG. 16 is a plan view illustrating conductive bumps on a package substrate in FIG. 15. FIG. 17 is an enlarged plan view illustrating portion ‘G’ in FIG. 16. FIG. 18 is a cross-sectional view taken along the line H-H′ in FIG. 17. FIG. 19 is a cross-sectional view taken along the line I-I′ in FIG. 17. FIG. 20 is a cross-sectional view taken along the line J-J′ in FIG. 17.

Referring to FIGS. 9 to 11, a plurality of conductive bumps 300 may be formed on chip pads 230 of a semiconductor chip 200.

In example embodiments, the conductive bumps 300 may be formed on the chip pads 230 of a wafer W including the semiconductor chips in a wafer level.

As illustrated in FIG. 9, the wafer W may include a substrate 210 and the chip pads 230 provided in a first surface 212 of the substrate 210. The wafer W may include a wiring layer 220 on an active surface, that is, the first surface 212 of the substrate 210. For example, the chip pads 230 may be provided in the outermost insulating layer of the wiring layer 220. The wafer W may include a die region DA where circuit patterns and cells are formed and a scribe lane region SA surrounding the die region DA. As described later, the substrate 210 may be cut along the scribe lane region SA that divides the plurality of die regions DA of the wafer W to be individualized or singulated.

For example, the substrate 210 may include silicon, germanium, silicon-germanium, or III-V compounds, e.g., GaP, GaAs, GaSb, etc. In some embodiments, the substrate 210 may be a silicon-on-insulator (SOI) substrate, or a germanium-on-insulator (GOI) substrate.

Circuit patterns may be provided in the active surface of the substrate 210. The circuit patterns may include transistors, diodes, etc. The circuit patterns may constitute circuit elements. The chip pad 230 may be electrically connected to the circuit element by wiring in the wiring layer.

The semiconductor chip 200 may include a memory chip such as a DRAM device or a flash memory device, or a non-memory chip such as a logic chip. The chip pads 230 may have a center pad type pad structure where the chip pads 230 are arranged in a row along a center line. For example, two chip pads 230 adjacent to each other may be arranged in a row along the center line.

As illustrated in FIG. 10, the plurality of conductive bumps 300 may be formed on the plurality of chip pads 230.

A protective layer 240 may be formed on the wiring layer 220 to expose at least portions of the chip pads 230, and a seed layer may be formed on the chip pads 230. For example, the protective layer 240 may include oxide, nitride, etc. These may be used alone or in a mixture thereof. Alternatively, the protective layer 240 may be a polymer layer formed by a spin coating process or a spray process. For example, the chip pad 230 may include a conductive metal such as copper (Cu) or aluminum (Al), and the protective layer 240 may include a resin such as photosensitive polyimide (PSPI).

The seed layer may include an alloy layer made of titanium/copper (Ti/Cu), titanium/palladium (Ti/Pd), titanium/nickel (Ti/Ni), chromium/copper (Cr/Cu), or a combination thereof. The seed layer may be formed by a sputtering process.

A photoresist pattern 24 having openings that expose portions of the seed layer over the chip pad 230 may be formed on the first surface 212 of the substrate 210, and the openings of the photoresist pattern may be filled with a metal material to form connection pillars 310. The metal material may include nickel (Ni), copper (Cu), palladium (Pd), platinum (Pt), etc.

A solder layer 320 may be formed on the connection pillar 310 within the opening of the photoresist pattern. The solder layer 320 may be formed on an end portion of the connection pillar 310. The solder layer 320 may include a metal material that has a lower melting point than the metal material of the connection pillar 310 and is in a solid state at room temperature. For example, the solder layer 320 may include a solder material. The solder layer 320 may include tin (Sn), tin/silver (Sn/Ag), tin/copper (Sn/Cu), tin/indium (Sn/In), etc. The photoresist pattern may be removed and a portion of the seed layer exposed by the connection pillar 310 may be removed to form a seed layer pattern 302.

The connection pillar 310 may have a rectangular cross-sectional shape with a long side and a short side. The long side of the connection pillar 310 may be within a range of 40 μm to 80 μm, and the short side of the connection pillar 310 may be within a range of 30 μm to 60 μm. A height (thickness) of the connection pillar 310 may be within a range of 20 μm to 50 μm. A height (thickness) of the solder layer 320 may be within a range of 5 μm to 20 μm.

As illustrated in FIG. 11, the wafer W may be cut along the scribe lane region SA by a sawing process to form an individualized semiconductor chip 200.

Before performing the sawing process, a second surface 214 of the substrate 210 may be polished such that the substrate 210 has a desired thickness.

Referring to FIGS. 12 to 14, a package substrate 100 having a chip mounting region MR and at least one pad open region POR provided in the chip mounting region MR may be provided. The package substrate 100 may include wirings 120 having a plurality of pad patterns PP that respectively extend such that at least a portion of each pad pattern is exposed within at least one pad open area POR.

In example embodiments, the package substrate 100 may be a multilayer circuit board having an upper surface 102 and a lower surface 104 opposite to the upper surface 102. For example, the package substrate 100 may be a printed circuit board (PCB) including wirings provided in a plurality of layers and vias connected to the wirings.

As illustrated in FIG. 12, the package substrate 100 may include a plurality of stacked insulating layers 110 and wirings 120a, 120b, 120c, and 120d respectively provided in the insulating layers.

In particular, first, second, third, fourth and fifth insulating layers 110a, 110b, 110c, 110d, and 110e may be sequentially stacked. The first insulating layer 110a may be an upper cover insulating layer, the second insulating layer 110b may be an upper insulating layer, the third insulating layer 110c may be a core layer, the fourth insulating layer 110d may be a lower insulating layer, and the fifth insulating layer 110e may be a lower cover insulating layer. The third insulating layer 110c as the core layer may include a non-conductive material layer. The third insulating layer 110c may include a reinforcing polymer or the like.

For example, the insulating layer may include an insulating material having a thermosetting resin such as epoxy resin or a thermoplastic resin such as polyimide. The insulating layer may include a resin impregnated into a core material such as organic fiber (glass fiber), for example, prepreg, FR-4, or BT (Bismaleimide Triazine).

A second wiring 120b may be formed on an upper surface of the third insulating layer 110c. The second insulating layer 110b may cover a second wiring 120b on the upper surface of the third insulating layer 110c. A first wiring 120a may be formed on the upper surface of the second insulating layer 110b and may be electrically connected to the second wiring 120b through an opening formed in the second insulating layer 110b.

A third wiring 120c may be formed on a lower surface of the third insulating layer 110c. The fourth insulating layer 110d may cover the third wiring 120c on the lower surface of the third insulating layer 110c. A fourth wiring 120d may be formed on a lower surface of the fourth insulating layer 110d and may be electrically connected to the third wiring 120c through an opening formed in the fourth insulating layer 110d.

The first to fourth wirings 120a, 120b, 120c, and 120d may be referred to as first to fourth circuit layers stacked in a thickness direction from the upper surface 102 to the lower surface 104 of the package substrate 100. For example, the wiring may include metal materials such as copper, aluminum, etc. It will be understood that the arrangements and numbers of the insulating layers and the wirings are exemplary, and not limited thereto.

A conductive through via 112 may penetrate the third insulating layer 110c as the core layer and electrically connect the second wiring 120b and the third wiring 120c. The first wiring 120a may be exposed from the upper surface 102 of the package substrate 100. The fourth wiring 120d may be exposed from the lower surface 104 of the package substrate 100.

An upper insulating layer 150 may be formed on the upper surface 102 of the package substrate 100, and may expose at least a portion of the first wiring 120a. A lower insulating layer 152 may be formed on the lower surface 104 of the package substrate 100, and may expose at least a portion of the fourth wiring 120d. The upper insulating layer 150 and the lower insulating layer 152 may separate the circuit patterns of the package substrate 100 from the external environment to reduce or prevent contamination and electrically insulate the wirings of the circuit pattern from each other. For example, the upper insulating layer and the lower insulating layer may include a photosensitive resin such as photo epoxy or a photosensitive polymer such as photo solder resist (PSR).

In addition, the first wiring 120a may include a data signal wiring 120a-1 for transmitting data signals to the semiconductor chip 200 mounted on the package substrate 100 and a power/ground wiring 120a-2 for transmitting a power signal or a ground signal to the semiconductor chip 200. The data signal wiring 120a-1, which functions as a data transmission pattern, may be provided as a single wire line, and the power/ground wiring 120a-2, which functions as a power pattern or ground wire, may be provided as a plurality of wire lines and may be electrically connected to each other.

As illustrated in FIG. 13, the upper insulating layer 150 may expose portions of the wirings 120a within the at least one pad open region POR. The pad open region POR may correspond to a center pad area where the chip pads 230 of the semiconductor chip 200 are arranged. Portions of the first wirings 120a in the pad open region POR exposed by the upper insulating layer 150 may be referred to as the pad patterns PP on which conductive bumps 300 are disposed respectively such that the semiconductor chip 200 is mounted by the flip chip bonding method.

The plurality of pad patterns PP may be arranged to be laterally spaced apart from each other along one side of the pad open region POR. For example, the plurality of pad patterns PP may include a first group of pad patterns PP1 and a second group of pad patterns PP2 that are laterally spaced apart from each other in a first direction (X direction). The first group of pad patterns PP1 may be arranged to be laterally spaced apart from each other in a second direction (Y direction) perpendicular to the first direction along a first side E1 of the pad open region POR, and the second group of pad patterns PP2 may be arranged to be laterally spaced apart from each other in the second direction (Y direction) along a second side E2 that faces the first side E1 of the pad open region POR. The first group of pad patterns PP1 and the second group of pad patterns PP2 may be symmetrical to each other with respect to a center line ML of the pad open region POR extending parallel to the second direction (Y direction).

As illustrated in FIG. 14, each of the pad patterns PP may include a main line 132 and a branch line 140. The main line 132 may extend in a third direction from one side (E1, E2) of the pad open region POR inwardly. The first wiring 120a may include a wiring line 130 covered by the upper insulating layer 150 and the main line 132 exposed by the upper insulating layer 150.

The branch line 140 may extend in a fourth direction different from the third direction at a position laterally spaced apart from an end portion 133 of the main line 132 by a predetermined distance L2. The branch line 140 may extend from one side wall 132a of the main line 132 in the fourth direction. An angle θ between the main line 132 and the branch line 140 may be greater than, less than, or equal to 90 degrees. For example, the third direction may be parallel to X direction, and the fourth direction may be parallel to Y direction.

For example, the branch line 140 may be laterally spaced apart from one side E2 of the pad open region POR by a first distance L1. The first distance L1 may be within a range of 20 μm to 40 μm. The branch line 140 may extend a third length L3 in the fourth direction. The third length L3 of the branch line 140 may be within a range of 10 μm to 30 μm. The lateral spacing distance L2 from the end portion 133 of the main line 132 to the branch line 140 may be within a range of 50 μm to 100 μm. The first width W1 of the main line 132 and the second width W2 of the branch line 140 may be within a range of 10 μm to 30 μm.

The branch lines 140 of the first group of pad patterns PP1 arranged along the first side E1 of the pad open region POR may extend in the same direction (fourth direction). The branch lines 140 of the second group of pad patterns PP2 arranged along the second side E2 of the pad open region POR may extend in the same direction (fourth direction).

Referring to FIGS. 15 to 20, the semiconductor chip 200 may be mounted on the package substrate 100.

As illustrated in FIGS. 15 and 16, in example embodiments, the semiconductor chip 200 may be mounted on the package substrate 100 using a flip chip bonding method. In this case, the semiconductor chip 200 may be mounted on the package substrate 100 such that the active surface on which the chip pads 230 are formed, that is, the first surface 212, faces the package substrate 100.

When the semiconductor chip 200 is placed on the package substrate 100, a portion of the main line 132 between the end portion 133 of the main line 132 and a branched portion of the main line 132 to which the branch line 140 is connected may serve as a landing pad on which the conductive bump 300 is disposed. The conductive bump 300 may be disposed on the portion of the main line 132, and during a thermal compression process, the solder layer 320 may be heated and softened, and flow along the main line 132 and the branch line 140 and then bonded.

As illustrated in FIGS. 17 and 18, in the first group of pad patterns PP1 and the second group of pad patterns PP2 spaced apart from each other in the first direction (X direction), during the thermal compression process, the solder layers 320 of the first and second groups may flow in directions A1 and A2 away from each other and then be bonded to portions of the branch lines 140, respectively. That is, the solder 320 may flow away from ends 133 of adjacent main lines 132 and towards the branch lines 140.

As illustrated in FIG. 19, in the second group of pad patterns PP2 spaced apart from each other in the second direction (Y direction), during the thermal compression process, each solder layer 320 may flow in the same direction A4 (second direction) and then be bonded to the portion of the branch line 140.

As illustrated in FIG. 20, during the thermal compression process, a portion of the solder layer 320 may flow in the direction A4 and the direction A2 along the main line 132 and the branch line 140 and then may be cured to fill a space between the side wall 132a of the main line 132 and one side wall of the branch line 140.

Referring to FIG. 21, a molding member 400 may be formed on the package substrate 100 to cover the semiconductor chip 200. For example, molding member 400 may include an insulating material such as epoxy molding compound.

For example, a molded underfill (MUF) process may be performed using a transfer molding apparatus. After placing the semiconductor chip 200 on the package substrate 100 in a cavity between a lower mold and an upper mold of the molding apparatus, a sealing material, which is a mold resin, may be injected into the cavity to mold the semiconductor chip while the upper mold and the lower mold are clamped. For example, the sealing material may include epoxy mold compound (EMC).

When the sealing material is injected into the cavity during the molded underfill (MUF) process, an air inside the cavity may be exhausted to the outside through a sealant passage hole formed in the package substrate 100, thereby improving resin filling properties. The sealing material may fill a space between the package substrate 100 and the semiconductor chip 200.

External connection members such as solder balls are formed on external connection pads on the lower surface 104 of the package substrate 100, that is, on portions of the fourth wiring 120d exposed by the lower insulating layer 152 to complete the semiconductor package 10 of FIG. 1.

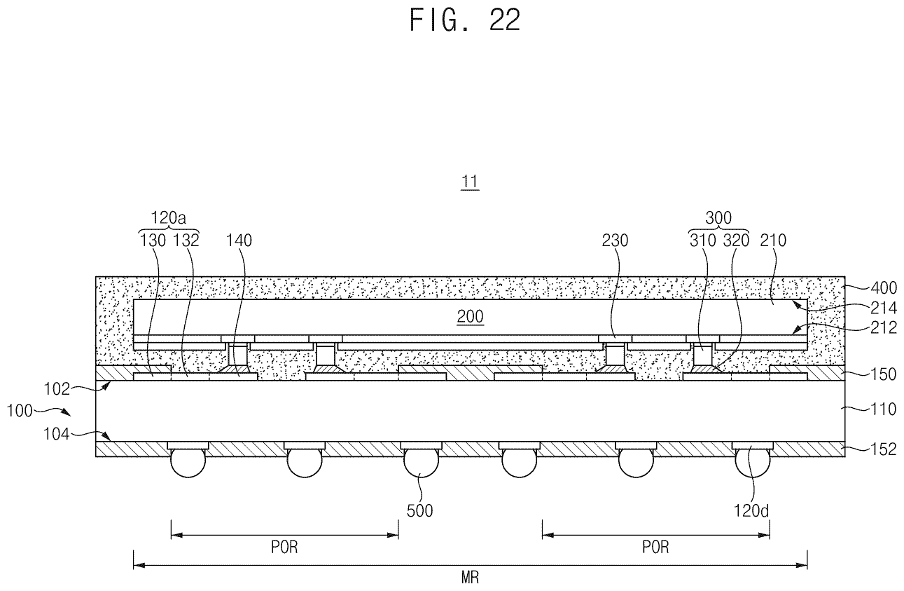

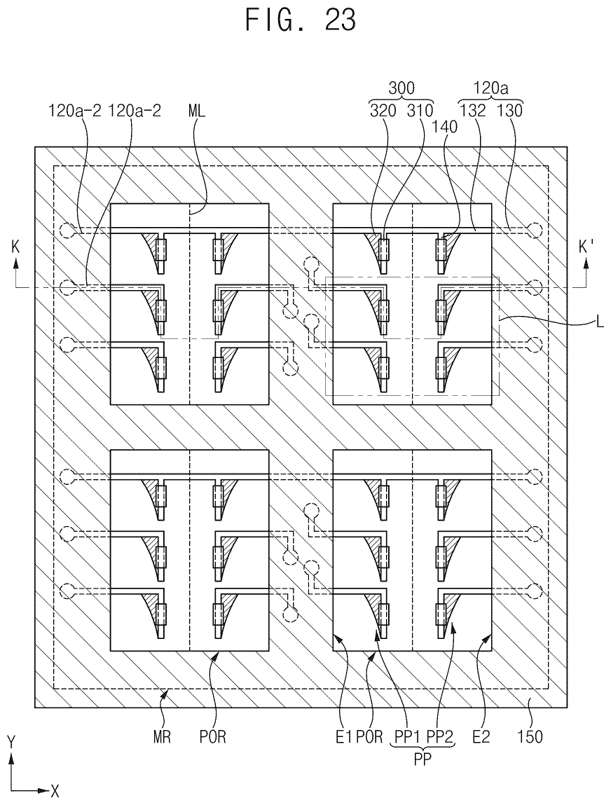

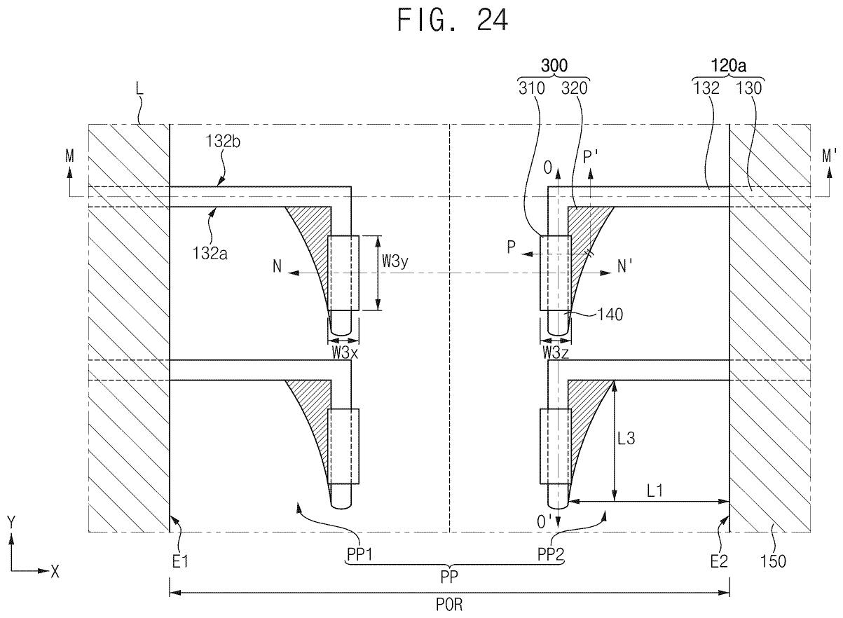

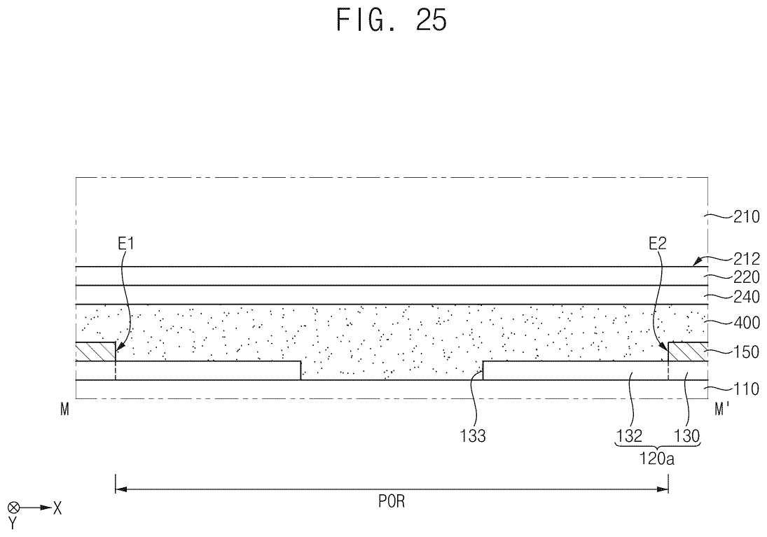

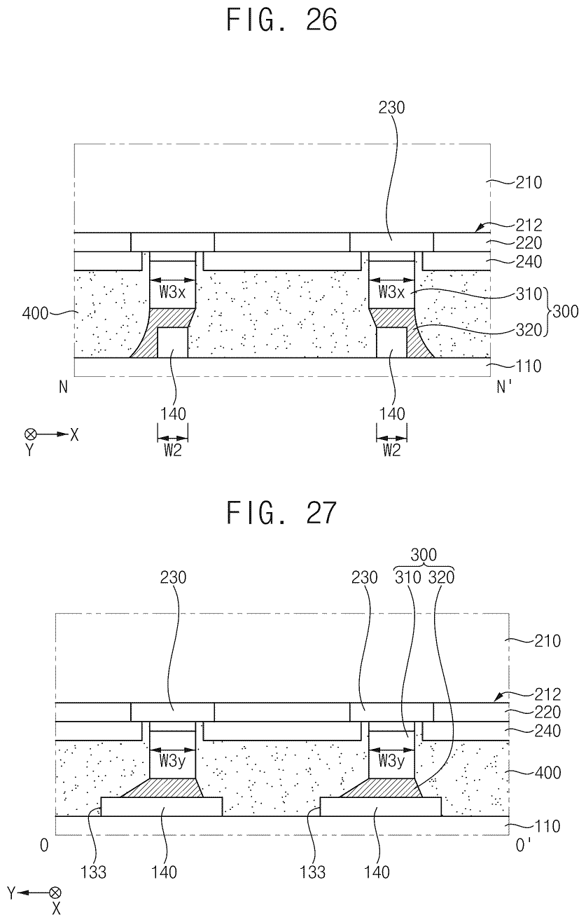

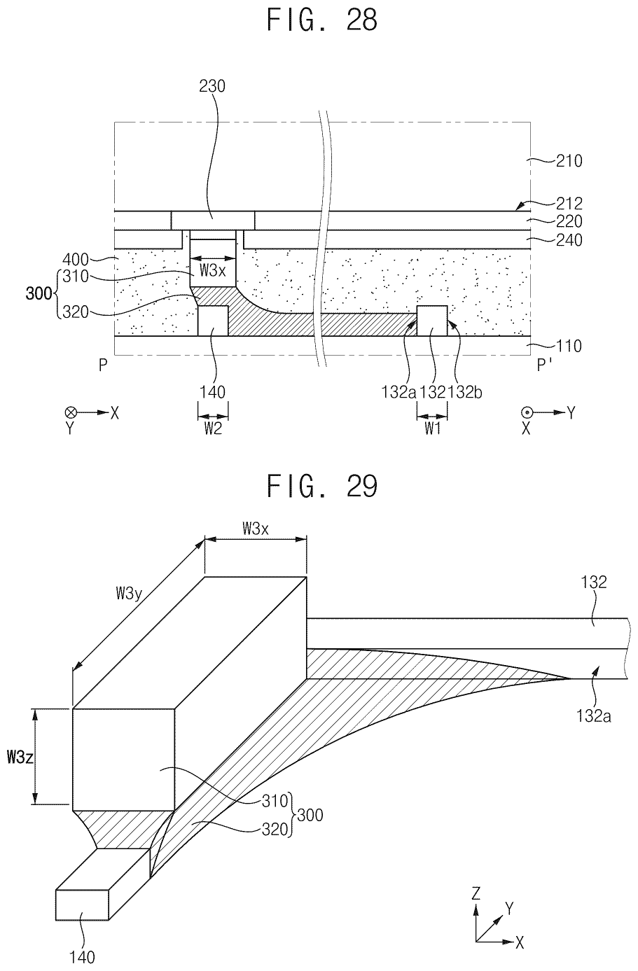

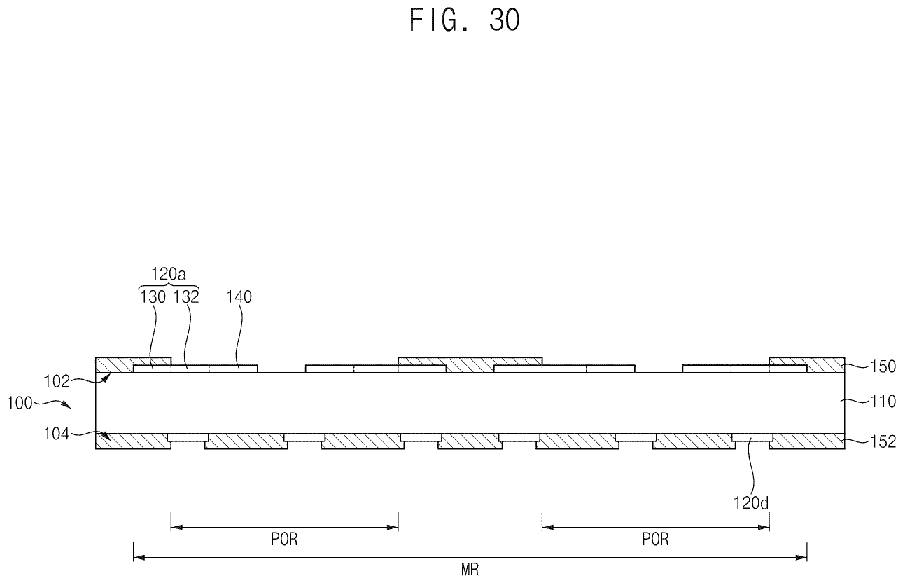

FIG. 22 is a cross-sectional view illustrating a semiconductor package in accordance with example embodiments. FIG. 23 is a plan view illustrating conductive bumps on a package substrate in FIG. 22. FIG. 24 is an enlarged plan view illustrating portion ‘L’ in FIG. 23. FIG. 25 is a cross-sectional view taken along the line M-M′ in FIG. 24. FIG. 26 is a cross-sectional view taken along the line N-N′ in FIG. 24. FIG. 27 is a cross-sectional view taken along the line O-O′ in FIG. 24. FIG. 28 is a cross-sectional view taken along the line P-P′ in FIG. 24. FIG. 29 is a perspective view illustrating a conductive bump bonded on a pad pattern of FIG. 23. FIG. 22 is a cross-sectional view taken along the line K-K′ in FIG. 23. The semiconductor package may be substantially the same as or similar to the semiconductor package described with reference to FIGS. 1 to 8 except for arrangements of pad open regions, pad patterns and conductive bumps. Thus, same reference numerals will be used to refer to the same or like elements and any further repetitive explanation concerning the above elements will be omitted.

Referring to FIGS. 22 to 29, a package substrate 100 of a semiconductor package 11 may have a chip mounting region MR and a plurality of pad open regions POR provided within the chip mounting region MR. The package substrate 100 may include wirings having a plurality of pad patterns PP that respectively extend such that at least a portion of the pad pattern is exposed within each pad open region POR.

As illustrated in FIG. 23, the plurality of pad open regions POR may be arranged in an array form on the package substrate 100. An upper insulating layer 150 may expose portions of the wirings 120a within each pad open region POR. Portions of first wirings 120a in the pad open region POR exposed by the upper insulating layer 150 may be referred to as the pad patterns PP on which conductive bumps 300 are disposed respectively such that the semiconductor chip 200 is mounted by a flip chip bonding method. Although four pad open regions POR are illustrated, it will be understood that it is not limited thereto.

In addition, the first wirings 120a may include a data signal wiring 120a-1 for transmitting data signals to the semiconductor chip 200 mounted on the package substrate 100 and a power/ground wiring 120a-2 for transmitting a power signal or a ground signal to the semiconductor chip 200.

The plurality of pad patterns PP may be arranged to be laterally spaced apart from each other along one side of the pad open region POR. For example, the plurality of pad patterns PP may include a first group of pad patterns PP1 and a second group of pad patterns PP2 that are laterally spaced apart from each other in a first direction (X direction). The first group of pad patterns PP1 may be arranged to be laterally spaced apart from each other in a second direction (Y direction) perpendicular to the first direction along a first side E1 of the pad open region POR, and the second group of pad patterns PP2 may be arranged to be laterally spaced apart from each other in the second direction (Y direction) along a second side E2 that faces the first side E1 of the pad open region POR.

The first group of pad patterns PP1 and the second group of pad patterns PP2 may be symmetrical to each other with respect to a center line ML of the pad open region POR extending parallel to the second direction (Y direction). The first group of pad patterns PP1 arranged along the second direction (Y direction) may have the same shapes. The second group of pad patterns PP2 arranged along the second direction (Y direction) may have the same shapes.

As illustrated in FIG. 24, each of the pad patterns PP may include a main line 132 and a branch line 140. The main line 132 may extend in a third direction from one side (E1, E2) of the pad open region POR inwardly. The first wiring 120a may include a wiring line 130 covered by the upper insulating layer 150 and the main line 132 exposed by the upper insulating layer 150.

The branch line 140 may extend from an end portion 133 of the main line 132 in a fourth direction different from the third direction. The branch line 140 may extend from one side wall 132a of the main line 132 in the fourth direction. An angle θ between the main line 132 and the branch line 140 may be greater than, less than, or equal to 90 degrees. For example, the third direction may be parallel to X direction, and the fourth direction may be parallel to Y direction.

The branch lines 140 of the first group of pad patterns PP1 arranged along the first side E1 of the pad open region POR may extend in the same direction (fourth direction). The branch lines 140 of the second group of pad patterns PP2 arranged along the second side E2 of the pad open region POR may extend in the same direction (fourth direction).

When the semiconductor chip 200 is placed on the package substrate 100, a portion of the branch line 140 may serve as a landing pad on which the conductive bump 300 is disposed. The conductive bump 300 may be disposed on the portion of the branch line 140, and during a thermal compression process a solder layer 320 may be heated and softened, and flow along one side wall of the branch line 140 and the main line 132 and then bonded.

As illustrated in FIGS. 25 and 26, in the first group of pad patterns PP1 and the second group of pad patterns PP2 spaced apart from each other in the first direction (X direction), each solder layer 320 may flow in directions away from each other (opposite directions) along the main line 130 and be joined to a portion of the main line 130. Accordingly, it may be possible to reduce or prevent short circuit defects from occurring due to overflow of the solder layer 320 between adjacent main lines 132 and branch lines 140 of the first group of pad patterns PP1 and the second group of pad patterns PP2.

As illustrated in FIG. 27, in the second group of pad patterns PP2 spaced apart from each other in the second direction (Y direction) along one side E2 of the pad open region POR, each solder layer 320 may be joined to portions of the main line 132 extending in a third direction different from the direction in which the branch line 140 extends. Accordingly, it may be possible to reduce or prevent short circuit defects from occurring between adjacent main lines 132 and branch lines 140 due to overflow of the solder layer 320.

As illustrated in FIGS. 28 and 29, a portion of the solder layer 320 may flow from the branch line 140 to the main line 132 and then hardens to fill a space between one side wall of the branch line 140 and the side wall 132a of the main line 132.

For example, the branch line 140 may be spaced apart from one side E2 of the pad open region POR by a first distance L1. The first distance L1 may be within a range of 20 μm to 40 μm. The branch line 140 may extend a third length L3 in the fourth direction. The third length L3 of the branch line 140 may be within a range of 50 μm to 100 μm. A first width W1 of the main line 132 and a second width W2 of the branch line 140 may be within a range of 10 μm to 30 μm.

A long side (W3y) of the connection pillar 310 may be within a range of 40 μm to 80 μm, and a short side (W3x) of the connection pillar 310 may be within a range of 30 μm to 60 μm. An extending direction of the long side W3y of the connection pillar 310 may be parallel to the fourth direction, and an extending direction of the short side W3x of the connection pillar 310 may be parallel to the third direction. A height W3z of the connection pillar 310 may be within a range of 20 μm to 50 μm. A height (thickness) of the solder layer 320 may be within a range of 5 μm to 20 μm.

As mentioned above, each of the plurality of pad patterns PP may include the main line 132 extending in the third direction from one side E1, E2 of the pad open region POR inwardly and the branch line 140 extending from the end portion 133 of the main line 132 in the fourth direction different from the third direction. Each of the conductive bumps 300 may be disposed on the portion of the branch line 140.

The branch lines 140 may be formed to extend in the same direction (fourth direction), so that each solder layer 320 of the conductive bumps 300 may flow to the main line 132 extending in the same direction (third direction), and may be joined to the portion of the main line 132. Accordingly, it may be possible to reduce or prevent short circuit defects from occurring between adjacent main line 132 and branch line 140 due to overflow of the solder layer 320.

Hereinafter, a method of manufacturing the semiconductor package in FIG. 22 will be explained.

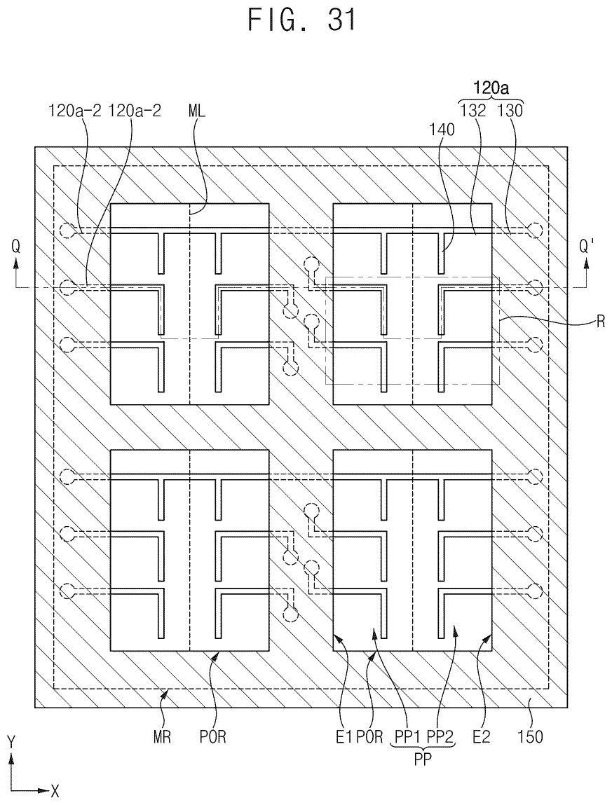

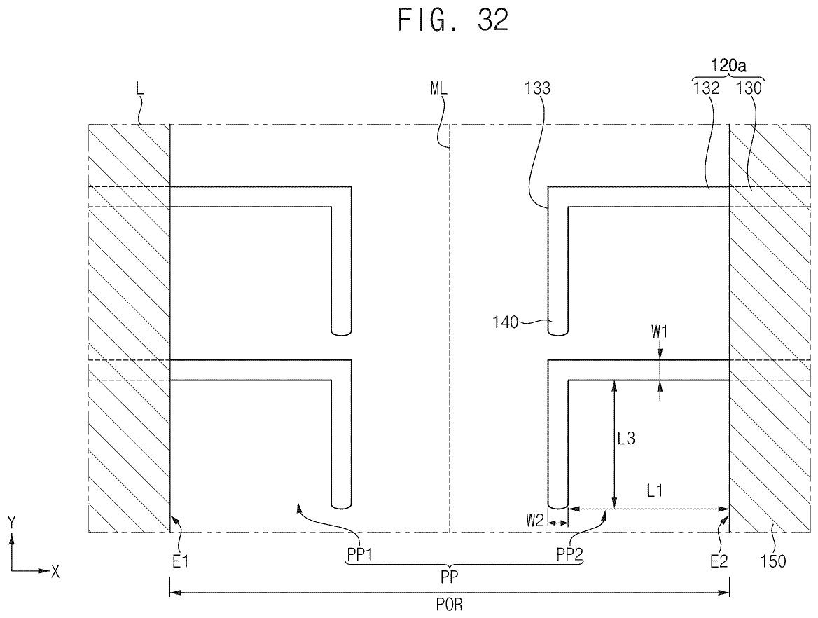

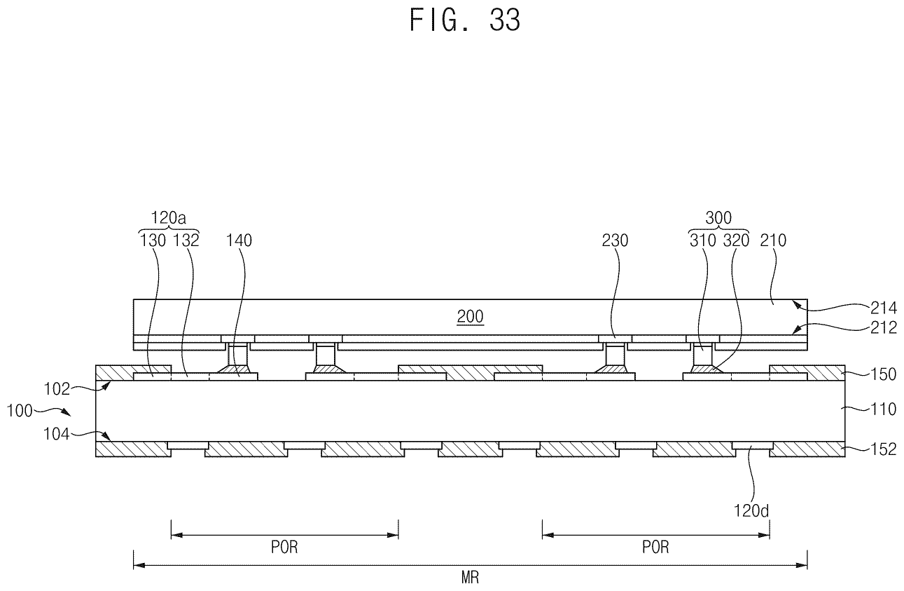

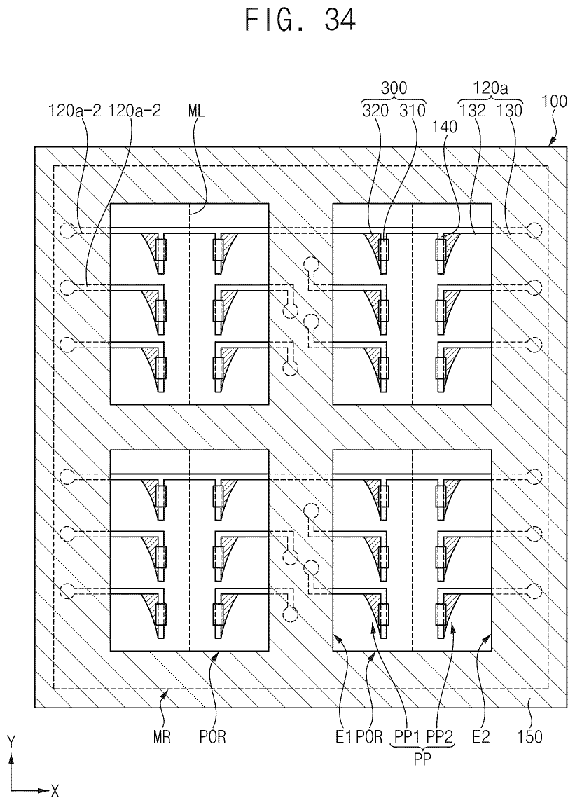

FIGS. 30 to 35 are cross-sectional views illustrating a method of manufacturing a semiconductor package in accordance with example embodiments. FIGS. 30, 33 and 35 are cross-sectional views illustrating a method of manufacturing a semiconductor package in accordance with example embodiments. FIG. 31 is a plan view of FIG. 30. FIG. 32 is an enlarged plan view illustrating portion ‘R’ in FIG. 31. FIG. 34 is a plan view illustrating conductive bumps on a package substrate in FIG. 33. FIG. 30 is a cross-sectional view taken along line Q-Q′ in FIG. 31.

Referring to FIG. 30, a package substrate 100 having a chip mounting region MR and a plurality of pad open regions POR provided within the chip mounting region MR may be provided. The package substrate 100 may include wirings having a plurality of pad patterns PP that respectively extend such that at least a portion of the pad pattern is exposed within each pad open region POR.

The package substrate 100 may include a plurality of stacked insulating layers 110 and wirings 120a and 120d respectively provided in the insulating layers. An upper insulating layer 150 may be formed on an upper surface 102 of the package substrate 100, and may expose at least a portion of the first wiring 120a. A lower insulating layer 152 may be formed on a lower surface 104 of the package substrate 100, and may expose at least a portion of a fourth wiring 120d. The package substrate 100 may be substantially the same as or similar to the package substrate of FIG. 1. Thus, descriptions on the same or similar elements of the package substrate will be omitted.

As illustrated in FIG. 31, the plurality of pad open regions POR may be arranged in an array form on the package substrate 100. The upper insulating layer 150 may expose portions of the wirings 120a within each pad open region POR. Portions of the first wirings 120a in the pad open region POR exposed by the upper insulating layer 150 may be referred to as the pad patterns PP on which conductive bumps 300 are disposed respectively such that the semiconductor chip 200 is mounted by a flip chip bonding method. Although four pad open regions POR are illustrated, it will be understood that it is not limited thereto.

In addition, the first wirings 120a may include a data signal wiring 120a-1 for transmitting data signals to the semiconductor chip 200 mounted on the package substrate 100 and a power/ground wiring 120a-2 for transmitting a power signal or a ground signal to the semiconductor chip 200.

The plurality of pad patterns PP may be arranged to be spaced apart from each other along one side of the pad open region POR. For example, the plurality of pad patterns PP may include a first group of pad patterns PP1 and a second group of pad patterns PP2 that are spaced apart from each other in a first direction (X direction). The first group of pad patterns PP1 may be arranged to be spaced apart from each other in a second direction (Y direction) perpendicular to the first direction along a first side E1 of the pad open region POR, and the second group of pad patterns PP2 may be arranged to be spaced apart from each other in the second direction (Y direction) along a second side E2 that faces the first side E1 of the pad open region POR. The first group of pad patterns PP1 and the second group of pad patterns PP2 are symmetrical to each other with respect to a center line ML of the pad open region POR extending parallel to the second direction (Y direction).

As illustrated in FIG. 32, each of the pad patterns PP may include a main line 132 and a branch line 140. The main line 132 may extend in a third direction from one side (E1, E2) of the pad open region POR inwardly. The first wiring 120a may include a wiring line 130 covered by the upper insulating layer 150 and the main line 132 exposed by the upper insulating layer 150.

The branch line 140 may extend from an end portion 133 of the main line 132 in a fourth direction different from the third direction. The branch line 140 may extend from one side wall 132a of the main line 132 in the fourth direction. An angle θ between the main line 132 and the branch line 140 may be greater than, less than, or equal to 90 degrees. For example, the third direction may be parallel to X direction, and the fourth direction may be parallel to Y direction.

For example, the branch line 140 may be spaced apart from one side E2 of the pad open region POR by a first distance L1. The first distance L1 may be within a range of 20 μm to 40 μm. The branch line 140 may extend a third length L3 in the fourth direction. The third length L3 of the branch line 140 may be within a range of 50 μm to 100 μm. A first width W1 of the main line 132 and a second width W2 of the branch line 140 may be within a range of 10 μm to 30 μm.

The branch lines 140 of the first group of pad patterns PP1 arranged along the first side E1 of the pad open region POR may extend in the same direction (fourth direction). The branch lines 140 of the second group of pad patterns PP2 arranged along the second side E2 of the pad open region POR may extend in the same direction (fourth direction).

Referring to FIGS. 33 and 34, the semiconductor chip 200 may be mounted on the package substrate 100.

In example embodiments, the semiconductor chip 200 may be mounted on the package substrate 100 using a flip chip bonding method. In this case, the semiconductor chip 200 may be mounted on the package substrate 100 such that an active surface on which the chip pads 230 are formed, that is, a first surface 212, faces the package substrate 100.

The semiconductor chip 200 includes a plurality of chip pad regions arranged in an array form, and the chip pads 230 may be disposed within each chip pad region. The chip pad regions of the semiconductor chip 200 may be arranged to respectively correspond to the pad open regions POR of the package substrate 100. The semiconductor chip 200 may be a thermal test chip. The heat distribution of the chip (die) may be measured through the chip pads 230 of the semiconductor chip 200.

The plurality of conductive bumps 300 may be formed on the plurality of chip pads 230, respectively. Each of the plurality of conductive bumps 300 may include a connection pillar 310 that extends from the chip pad 230 of the semiconductor chip 200 and a solder layer 320 bonded to an end portion of the connection pillar 310.

When the semiconductor chip 200 is placed on the package substrate 100, a portion of the branch line 140 may serve as a landing pad on which the conductive bump 300 is disposed. The conductive bump 300 may be disposed on the portion of the branch line 140, and during a thermal compression process the solder layer 320 may be heated and softened, and flow along one side wall of the branch line 140 and the main line 132 and then bonded.

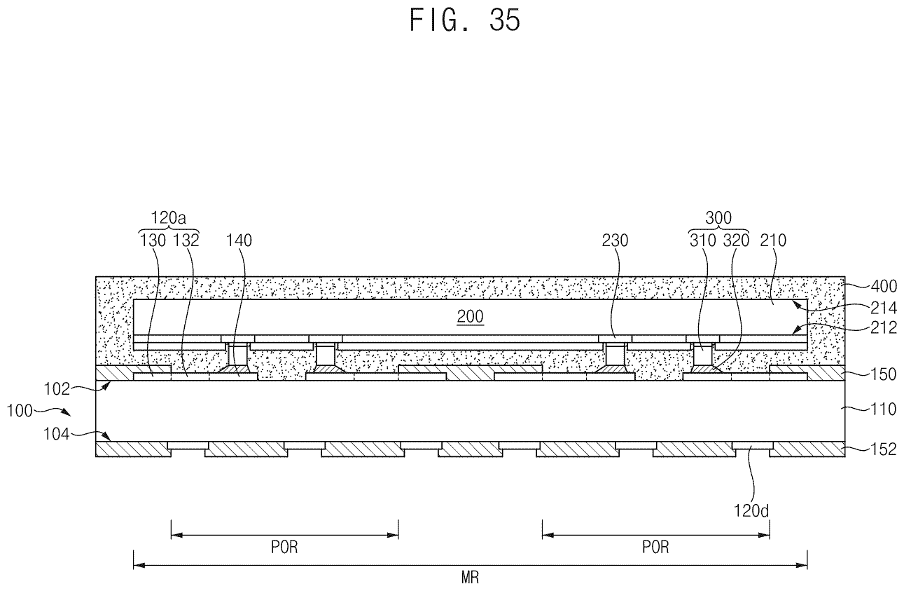

As illustrated in FIG. 35, during the thermal compression process, a portion of the solder layer 320 may flow from the branch line 140 to the main line 132 and then may be cured to fill a space between one side wall of the branch line 140 and the side wall 132a of the main line 132.

Referring to FIG. 35, a molding member 400 may be formed on the package substrate 100 to cover the semiconductor chip 200. The sealing member may include an epoxy mold compound (EMC).

For example, a molded underfill (MUF) process may be performed using a transfer molding apparatus. During the molded underfill (MUF) process, when a sealing material is injected into a cavity between a lower mold and an upper mold, an air inside the cavity may be exhausted to the outside through a sealant passage hole formed in the package substrate 100 to improve resin filling. The sealing material may fill a space between the package substrate 100 and the semiconductor chip 200.

External connection members such as solder balls may be formed on the external connection pads on the lower surface 104 of the package substrate 100, that is, on the portions of the fourth wiring 120d exposed by the lower insulating layer 152 to complete the semiconductor package 11 of FIG. 22.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A semiconductor package, comprising:
a package substrate comprising a chip mounting region and at least one pad open region in the chip mounting region, the package substrate including wirings having a plurality of pad patterns that respectively extend such that at least a portion of each of the pad patterns is exposed in the at least one pad open region;
a semiconductor chip mounted on the chip mounting region of the package substrate by a plurality of conductive bumps; and
a sealing member on the semiconductor chip on the package substrate,
wherein the plurality of pad patterns are laterally spaced apart from each other,
wherein the each of the pad patterns comprises:
a main line extending in a first direction away from one side of the pad open region; and
a branch line extending in a second direction different from the first direction,
wherein the branch line extends from an end portion of the main line, and each of the conductive bumps is on an upper surface of the branch line, or
wherein the branch line extends from a position laterally spaced apart from the end portion of the main line, and each of the conductive bumps is on an upper surface of a portion of the main line that is between the end portion and the position from which the branch line extends.

2. The semiconductor package of claim 1, wherein the branch line is laterally spaced apart from the one side of the pad open region by a distance of about 20 μm to about 40 μm in the first direction.

3. The semiconductor package of claim 1, wherein the branch line extends from the position laterally spaced apart from the end portion of the main line by a length of about 10 μm to about 30 μm in the second direction.

4. The semiconductor package of claim 1, wherein the branch line extends from the end portion of the main line by a length of about 50 μm to about 100 μm in the second direction.

5. The semiconductor package of claim 1, wherein the second direction is perpendicular to the first direction.

6. The semiconductor package of claim 1, wherein each of the plurality of conductive bumps comprises a connection pillar extending from a chip pad of the semiconductor chip and a solder layer on an end portion of the connection pillar opposite the chip pad.

7. The semiconductor package of claim 6, wherein the branch line extends from the position laterally spaced apart from the end portion of the main line, and the solder layer extends along a side wall of the main line to a side wall of the branch line to at least partially fill a space between the end portion of the main line and the branch line.

8. The semiconductor package of claim 7, wherein the connection pillar has a first side and a second side that is shorter than the first side, and an extension direction of the first side is parallel to the first direction.

9. The semiconductor package of claim 6, wherein the branch line extends from the end portion of the main line, and the solder layer extends from a side wall of the branch line to a side wall of the main line to at least partially fill a space between the branch line and the main line.

10. The semiconductor package of claim 9, wherein the connection pillar has a first side and a second side that is shorter than the first side, and an extension direction of the first side is parallel to the second direction.

11. A semiconductor package, comprising:
a package substrate comprising at least one pad open region, the package substrate including wirings having a plurality of pad patterns that respectively extend such that at least a portion of each of the pad patterns is exposed in the at least one pad open region;
a semiconductor chip comprising a plurality of chip pads on a first surface thereof and oriented such that the first surface faces an upper surface of the package substrate;
a plurality of conductive bumps on the plurality of chip pads, respectively, wherein the conductive bumps bond the plurality of chip pads to respective portions of the plurality of pad patterns; and
a sealing member on the semiconductor chip on the package substrate, the sealing member at least partially surrounding the plurality of conductive bumps between the package substrate and the semiconductor chip,
wherein the each of the pad patterns comprises:
a main line extending in a first direction away from one side of the pad open region; and
a branch line extending in a second direction different from the first direction from a position laterally spaced apart from an end portion of the main line, and
wherein each of the conductive bumps is on an upper surface of a portion of the main line that is between the end portion and the position from which the branch line extends.

12. The semiconductor package of claim 11, wherein the branch line is laterally spaced apart from the one side of the pad open region by a distance of about 20 μm to about 40 μm in the first direction.

13. The semiconductor package of claim 11, wherein the branch line has a length of about 10 μm to about 30 μm in the second direction.

14. (canceled)

15. The semiconductor package of claim 11, wherein each of the plurality of conductive bumps comprises a connection pillar extending from a respective one of the chip pads of the semiconductor chip and a solder layer on an end portion of the connection pillar opposite the respective one of the chip pads.

16. The semiconductor package of claim 15, wherein the solder layer extends along a side wall of the main line to a side wall of the branch line to at least partially fill a space between the end portion of the main line and the branch line.

17.-20. (canceled)

21. A semiconductor package, comprising:
a package substrate comprising at least one pad open region, the package substrate including wirings having a plurality of pad patterns that respectively extend such that at least a portion of each of the pad patterns is exposed in the at least one pad open region;
a semiconductor chip comprising a plurality of chip pads on a first surface thereof and oriented such that the first surface faces an upper surface of the package substrate;
a plurality of conductive bumps on the plurality of chip pads, respectively, wherein the conductive bumps bond the plurality of chip pads to respective portions of the plurality of pad patterns; and
a sealing member on the semiconductor chip on the package substrate, the sealing member at least partially surrounding the plurality of conductive bumps between the package substrate and the semiconductor chip,
wherein each of the pad patterns comprises:
a main line extending in a first direction away from one side of the pad open region; and
a branch line extending in a second direction different from the first direction from an end portion of the main line, and
wherein each of the conductive bumps is on an upper surface of the branch line.

22. The semiconductor package of claim 21, wherein the branch line is laterally spaced apart from the one side of the pad open region by a distance of about 20 μm to about 40 μm in the first direction.

23. The semiconductor package of claim 21, wherein the branch line has a length of about 50 μm to about 100 μm in the second direction.

24. (canceled)

25. The semiconductor package of claim 21, wherein each of the plurality of conductive bumps comprises a connection pillar extending from a respective one of the chip pads of the semiconductor chip and a solder layer on an end portion of the connection pillar opposite the respective one of the chip pads.

26. The semiconductor package of claim 25, wherein the solder layer extends along a side wall of the branch line to a side wall of the main line to at least partially fill a space between the branch line and the main line.

27.-30. (canceled)
